(19) United States
(12) Patent Application Publication
(10) Pub. No.: US 2011/0102093 A1
(43) Pub. Date: May 5, 2011

(54) INTEGRATED OSCILLATOR CIRCUIT HAVING AT LEAST TWO RESONANT CIRCUITS

(75) Inventors: Samir El Rai, Duesseldorf (DE); Ralf Tempel, Duisburg (DE)

(73) Assignee: ATMEL DUISBURG GMBH, Duisburg (DE)

(21) Appl. No.: 12/296,501

(22) PCT Filed: Mar. 31, 2007
(86) PCT No.: PCT/EP2007/002913

§ 371 Date: Sep. 21, 2009

(30) Foreign Application Priority Data
Apr. 12, 2006 (DE) 10 2006 017 189.6

(51) Int. Cl. H03B 5/12

(52) U.S. Cl. 331/117 FE

(57) ABSTRACT

An integrated oscillator circuit (16) with an amplifier circuit (22) and a frequency-selective feedback network comprising a first resonant circuit (18) and a second resonant circuit (20) is proposed. The oscillator circuit is characterized in that the first resonant circuit (18) is connected to the amplifier circuit (22) solely on the output side and is formed as a parallel resonant circuit comprising a first capacitor (24) and a first inductor (26), and the second resonant circuit (20) is connected to the amplifier circuit (22) solely on the input side (36, 38) and is formed as a parallel resonant circuit comprising a second capacitor (32) and a second inductor (34).

The invention relates to an integrated oscillator circuit according to the preamble of claim 1.

An oscillator circuit of said type is known from International Pat. Appl. No. WO 99/43079. This publication shows a differential oscillator design with two resonant circuits, which are dedamped over an amplifier circuit comprising two transistors in a common-base circuit. In the terminology of WO 99/43079, the resonant circuits each have a resonant element, a feedback path, and a differential coupling element. The resonant element is to have preferably inductive components, whereas the feedback path is to be realizable, e.g., capacitively. A capacitor is given as an example of a differential coupling element. Both resonant circuits are connected to both an input and an output of the amplifier circuit.

In the subject matter of WO 99/43079, the alternating component of the voltage at the emitters of the transistors in a preferred embodiment (FIG. 2 therein) is determined by a capacitive voltage divider, which includes a capacitor, parallel to the collector-emitter path of the transistor, and the capacitor of the differential coupling element between the emitters. In this case, a certain AC portion of the collector voltage always declines of necessity across the differential coupling element at the expense of the emitter voltage limited thereby.

Because of the feedback path, oscillators of this type are also called feedback oscillators. Furthermore, so-called reflection oscillators are also known, for example, from the publication “Optimizing MMIC Reflection-type Oscillators,” 2004 IEEE MTT-S Digest, pages 1341ff. According to this publication, an oscillator of this type includes an active component, which is connected to AC ground across three impedors. In this case, two terminals are connected to ground so that a negative impedance arises at the third terminal. There, a third impedor is connected to AC ground to set the resonance frequency.

As already stated in WO 99/43079, in designing an oscillator, compromises must always be made between requirements, one of which can be fulfilled often only at the expense of another. Required are, for example, realizability in high quantities at the lowest possible cost, a small oscillator circuit place requirement, a low current consumption, a high signal-to-noise ratio, a low sensitivity to manufacturing-related variations in circuit properties, and a large bandwidth of adjustable resonance frequencies with a simultaneously high resonant circuit quality. In the subject matter of WO 99/43079, a high quality is to be achieved by capacitive switches at the collectors of the transistors and variable voltage capacitor tuning between the emitters. Additional tunability (tuning control) can be achieved by means of capacitive coupling between the collectors of the differential transistor pairs.

On this background, the object of the invention is to provide an integrated oscillator circuit with further improvement.

This object is achieved in an oscillator circuit of the aforementioned type in that the first resonant circuit is connected to the amplifier circuit solely on the output side and is formed as a parallel resonant circuit comprising a first capacitor and a first inductor, and the second resonant circuit is connected to the amplifier circuit solely on the input side and is formed as a parallel resonant circuit comprising a second capacitor and a second inductor.

The following advantages are achieved in this way:

A second resonant circuit of this type makes possible a low-noise setting of the amplitude at the input of the amplifier circuit.

In addition, the range of the possible control of the amplifier circuit is increased, as emerges from the following observation: In an ideal parallel resonant circuit without ohmic resistance, the AC resistance is infinitely large in the case of resonance, so that the parallel resonant circuit blocks current flow at its resonance frequency. When an ideal trap circuit of this type is used in a frequency-selective feedback network, the entire AC voltage therefore declines across the trap circuit, so that a maximum voltage amplitude is available at the input of the amplifier circuit. In the ideal case, the input voltage can reach the value of the output voltage. As a result, the amplifier circuit is controlled to the maximum; this generates a maximum output signal and therefore contributes to a good signal-to-noise ratio.

Depending on the choice of inductors and capacitors in the second resonant circuit, the amplitude of the voltage fed back in-phase to the input is set. In this case, components with fixed values can be used for the mentioned inductors and capacitors. These values can be established so that they together with the values for parasitic capacitors of the amplifier circuit together fulfill a resonance condition. Said parasitic capacitors are then decoupled at least partially from first resonant circuit. Because the bandwidth of the frequency tunability of resonant circuits is usually limited by fixed, parasitic capacitors, this partial decoupling leads to a reduction of the capacitors acting in the first resonant circuit and thereby to an increase in the mentioned bandwidth, and thus the frequency tuning range of the first resonant circuit.

Alternatively, in particular the capacitance of the second resonant circuit may also be variable, so that the amplitude of the voltage fed back in-phase to the input is variable. In the case of resonance, a relatively high voltage value may be set. With increasing distance from the resonance frequency, the amplitude at the input of the amplifier circuit declines. Whether the resonance case or a certain distance to the resonance case occurs can be set by changing the second resonant circuit capacitance.

In an embodiment of the amplifier circuit with bipolar transistors, transistor capacitances arise in each case between an AC ground and the base, emitter, and collector. By the low-noise setting of the voltage of the amplitude at the input of the amplifier circuit, therefore at the emitter or base of a transistor of the amplifier circuit, these parasitic transistor capacitances can be utilized for tunability of the oscillator circuit frequency. This possibility arises because the aforementioned capacitances depend on the signal amplitude at the input of the amplifier circuit. Said capacitances usually have high values, which are often more than 50% of the resonant circuit capacitance. Its effect on the width of the tuning range is accordingly great.

A preferred embodiment is characterized in that the first inductor is connected via a first DC current path to a first DC reference potential, and the second inductor is connected via a second DC current path to a second DC reference potential.

By connection of the second inductors to the second DC reference potential, the second DC current path, necessary for dedamping of the resonant circuits and operating point setting of the amplifier circuit, is routed over the second inductor to the amplifier circuit. Inductors are usually metallic and in the ideal case have an infinitesimally low ohmic resistance.

In the case of such low ohmic resistance values, small differences in the resistance values, as may occur owing to process variations during the manufacture of integrated oscillator circuits, play only a minor role. In the case of the conventional production of the DC connection of the amplifier circuit with use of resistors made of semiconductor material or with use of active current sources or current drains, containing transistors, in contrast, relatively large scattering of resistance values occurs owing to process variations.

In addition, the noise voltages u_r occurring in the lines depend on the value R of their resistors (u_r²=4k_{B}TR, k_{B}=Boltzmann's constant, T=absolute temperature).

Because of the low resistance values of the inductors, a low-noise DC connection of the amplifier circuit with a reduced variation range for the effect of process variations is provided by the invention.

Further embodiments relate to the geometry of the resonant circuit inductors and the arrangement of capacitors. The inductors can be nearly circular, having at least one turn or transmission line, and be divided into left inductors and right inductors by a center tap, to which in each case the DC supply is connected. It is understood that other embodiments may also have elliptical conductor loops.

The inductance values of both resonant circuit inductors are preferably the same, but can also assume different values, as a result of which a further degree of freedom is provided in circuit design.

Another embodiment has rectangular conductor loops as inductors, in which adjacent and parallel sections LC act as coupling capacitors and together with sections LL, orthogonal thereto, define the length, and/or area of a conductor loop and thereby the inductance.

It is therefore possible by changing the lengths LL and LC to vary the value of the inductance, the value of the coupling capacitance, and a portion of a capacitive and transformer coupling of the entire coupling. As a result, additional degrees of freedom in circuit design are provided.

Additional capacitors, which are connected between the parallel sections LC, enable optimization of the input and/or output impedance of transistors, functioning as amplifiers, in the amplifier circuit. When the amplifier circuit functions with common-base circuits of bipolar transistors, the additional capacitors are connected between collectors and emitters, which enables an optimized impedance adjustment. This then contributes to a maximum power amplification and noise adjustment and therefore also to a maximum signal/noise ratio.

Instead of a pure rectangular shape, circular shape, or elliptical shape, other embodiments can also have conductor loops with sections, straight in areas, with a regular or irregular, as well as convex or concave polygon shape and/or conductor loops with concave or convex sections, curved in areas, or hybrid shapes made of curved and straight sections.

Further embodiments are characterized by purely transformer or at least partially transformer feedback, which is achieved by an adjacent arrangement of the resonant circuit inductors of the two parallel resonant circuits. The transformer coupling has the advantage of a simplified circuit structure and a reduced space requirement, because no capacitors are needed for a capacitive coupling.

Other advantages emerge from the description and the appended figures.

It is understood that the aforementioned features and the features still to be explained hereafter can be used not only in the specifically indicated combination but also in other combinations or alone, without going beyond the scope of the present invention.

### DRAWINGS

Exemplary embodiments of the invention are presented in the drawings and are explained in greater detail in the following description. In schematic form, in each case the drawing shows in:

FIG. 1 a prior-art block diagram of an oscillator circuit;

FIG. 2 a first exemplary embodiment of the invention, which operates according to a differential principle;

FIG. 3 a first embodiment of an amplifier circuit with transistors in a common-base circuit;

FIG. 4 an embodiment of an amplifier circuit with transistors in a common-emitter circuit;

FIG. 5 embodiments of variable capacitors;

FIG. 6 possible geometric embodiments of resonant circuit inductors and the arrangement of capacitors;

FIG. 7 embodiments of oscillator circuits with a transformer feedback;

FIG. 8 an embodiment of an oscillator circuit in a single-ended design; and

FIG. 9 an embodiment of the invention as a reflection oscillator.

In this regard, the same reference numbers in all figures designate the same elements.

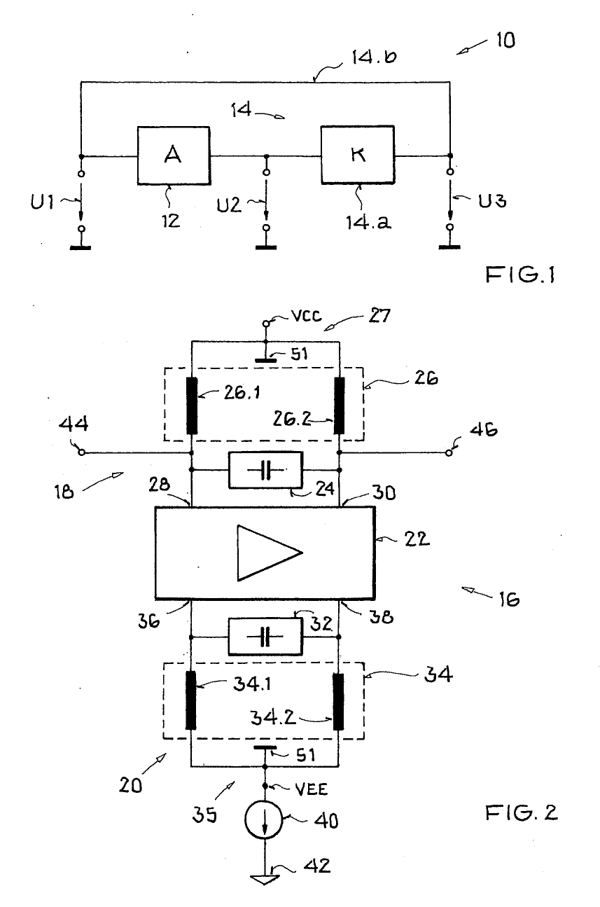

Specifically, FIG. 1 shows the prior-art principle of a feedback oscillator circuit 10, which generally includes an amplifier circuit 12 with a frequency-selective feedback network 14. Amplifier circuit 12 amplifies an input signal U1 to an output signal U2=A*U1. Feedback network 14 selects a resonance frequency from output signal U2 and returns the output signal of the selected frequency in damped form as signal U3=k*U2 back to the input. Stable oscillation of output signal U2, as is known, arises when the amplitude of the fed back signal U3 is the same as the amplitude of input signal U1. If the product of amplification A and damping k is called loop amplification g, g must therefore be equal to 1. Further, the phase shift between U1 and U3 must allow constructive interference, in the ideal case therefore constituting an integer multiple of 2π. These associations apply very generally and are known (compare Tietze Schenk, Halbleiterschaltungstechnik [Semiconductor Technology], 9^{th} edition, pages 458, 459). The feedback network can be divided still further into a first part 14.a, which selects the frequency, and a second part 14.b, which returns the selected signal back to the input.

FIG. 2 shows a first exemplary embodiment of the invention with an integrated oscillator circuit 16, which functions with differential signals. Oscillator circuit 16 has a first resonant circuit 18, a second resonant circuit 20, and an amplifier circuit 22 dedamping both resonant circuits 18, 20. First resonant circuit 18 is a parallel resonant circuit with a first capacitor 24 and a first inductor 26 and is connected to first terminals 28, 30 of amplifier circuit 22, which form the outputs of amplifier circuit 22. First capacitor 24 is located between the two first terminals 28, 30. One end of a partial capacitor 26.1 of first inductor 26 is connected to first terminal 28. One end of a partial capacitor 26.2 of first inductor 26 is also connected to second terminal 30. The complementary end of the two partial inductors 26.1, 26.2 is connected in addition via a first DC path 27, therefore without interconnection of capacitors, to a first DC reference potential VCC. The connection of the two partial inductors 26.1, 26.2 forms an AC ground 51.

Similarly, second resonant circuit 20 is also a parallel resonant circuit with a second capacitor 32 and a second inductor 34. It is connected to two terminals 36, 38 of amplifier circuit 22, which form the amplifier circuit inputs. Second capacitor 32 is located between the two second terminals 36, 38. A partial inductor 34.1, 34.2 of the second inductor 34 is connected in each case to each of the two terminals 36, 38. The complementary end of partial inductors 34.1, 34.2 of second inductor 34 is connected via a second DC path 35, therefore without interconnection of capacitors, to a second DC reference potential VEE. The connection of the two partial inductors 34.1, 34.2 also forms an AC ground 51.

The second reference potential VEE in the embodiment of FIG. 2 arises as an output potential of a current source 40, which is referred to a DC ground 42. Differential oscillator circuit 16 at the input of amplifier circuit 22 manages with only one current source 40, because the two partial inductors 34.1, 34.2 allow flow of direct currents from input 36 and 38 to AC ground 51 with negligible drops in the DC voltage. The two parallel resonant circuits 18, 20 in FIG. 2 correspond to the aforementioned first part 14.a of feedback network 14, which selects the frequency. The aforementioned second part 14.b, over which the actual feedback occurs, in the illustration in FIG. 2 is integrated into amplifier circuit 22. The output signal of oscillator circuit 16 is provided at terminals 44, 46.

It is of great advantage that this differential circuit requires only one current source 40 at the input of amplifier circuit 22, because DC potential differences at terminals 36, 38 of amplifier circuit 22 are completely prevented as a result. Such potential differences can occur in the aforementioned prior art owing to fabrication-related variations in the properties of the two current sources and lead there to different operating points of transistors functioning as amplifiers. These are then no longer controlled precisely in a differential manner, which has negative effects on the quality of the output signal of the oscillator circuit.

A very low resistance of the DC supply is achieved overall by the connection as taught by the invention of input 36, 38 of amplifier circuit 22 over second inductor 34 and second DC path 35 to the second DC potential VEE of the DC supply. Because of the differential embodiment, separate DC path sections to terminals 36, 38 of the differential input continue to be necessary. These sections, however, are realized by extremely low-impedance inductors. The total resistance of the DC supply is therefore dominated on the input side of the amplifier arrangement by components such as resistors or transistors of a DC supply current source, which are arranged in a circuit section common for both terminals of the differential input. Asymmetries in the amplifier circuit DC supply are almost completely avoided as a result of these influences.

Oscillator circuit 16 of FIG. 2, like the oscillator circuits described in other respects, is realized in a conventional semiconductor manufacturing process as an integrated circuit on a semiconductor substrate. In this case, inductors 26, 34 are preferably formed by patterned trace sections in metallization levels. Capacitors 24, 32 are formed, for example, with a thin oxide layer as a dielectric, which lies on a highly doped layer of semiconductor material and is covered by a metal layer (MIS=metal insulator semiconductor structure). MIM structures (metal insulator metal) may also be used.

FIG. 3 shows a first embodiment 22.1 of an amplifier circuit 22, as used in FIG. 2. In embodiment 22.1, amplifier circuit 22 has two bipolar transistors 48, 50 in a common-base circuit, whose bases are connected to one another and form an AC ground 51 at a point in the connection at which no AC signal occurs (AC ground). The collector of a first transistor 48 forms a first terminal 28 of amplifier circuit 22 and the collector of second transistor 50 forms the other first terminal 30. Accordingly, the emitter of first transistor 48 forms a second terminal 36 of amplifier circuit 22 and the emitter of second transistor 50 forms the other second terminal 38. Each emitter thereby forms an input of amplifier circuit 22 and each collector accordingly forms an output.

An input 36 (38) is connected to an output 28 (30) over a feedback, which in the embodiment of FIG. 3 in each case contains a coupling capacitor 52 (54). Coupling capacitor 52, 54, simply put, in each case forms an AC short circuit, while it blocks DC currents. It thereby permits collector and emitter DC potentials necessary particularly for the transistor function. In other respects, it has a greater capacitance value in comparison with first and second capacitor 24, 32 and is therefore not or only negligibly phase-rotating. A signal at the collector of one of the two transistors 48, 50 is therefore back coupled via the respective coupling capacitor 52, 54 with negligible phase rotation to the emitter of the same transistor 48, 50, as a result of which transistor 48, 50 is controlled at its emitter. In the case of control of this type, the signal at the collector as an output of amplifier circuit 22.1 follows the input signal at the emitter with the same phase.

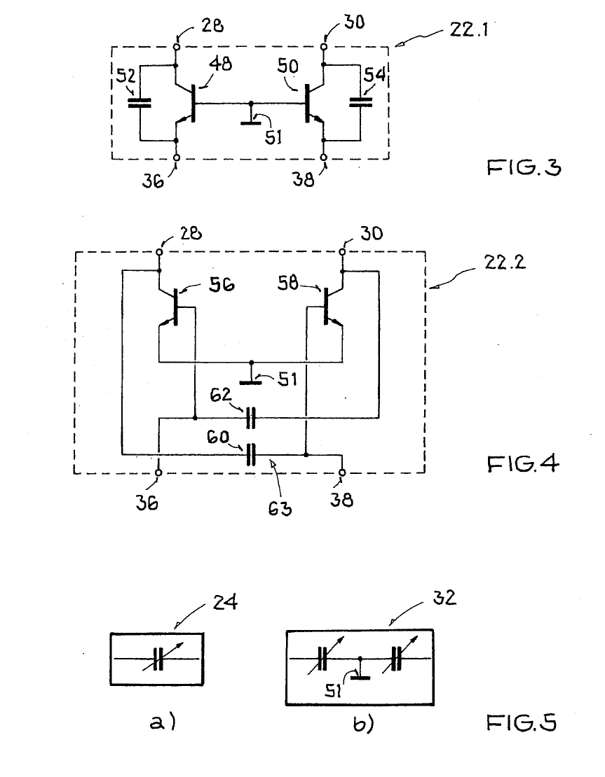

Alternatively to the embodiment according to FIG. 3, amplifier circuit 22 can also have two bipolar transistors 56, 58 in the common-emitter circuit, as is shown in FIG. 4 as embodiment 22.2. In this case, the emitters of the two transistors 56, 58 are connected to one another and at a point in the connection form an AC ground 51, at which the AC portions of both emitter potentials are compensated (AC ground). As in the embodiment of FIG. 3, the collector of a first transistor 56 of the two transistors 56, 58 forms one of the two first terminals 28, 30 of amplifier circuit 22 and the collector of second transistor 58 of the two transistors 56, 58 forms the other of the two first terminals 28, 30.

In contrast to the subject matter of FIG. 3, the base of first transistor 56 forms one of the two terminals 36, 38 of amplifier circuit 22 and the base of second transistor 58 forms the other of the two terminals 36, 38. Each base therefore forms an input 36, 38 of amplifier circuit 22 and each collector accordingly forms an output 28, 30. An output 28 (30) each is connected to an input 38 (36) via a feedback, which in each case contains a coupling capacitor 60, 62. These coupling capacitors 60, 62 also have relatively high capacitance values so that their phase-rotating action can be disregarded. A signal at the collector of one of the two transistors 56, 58 is coupled back via the respective coupling capacitor 62, 60 to the base of the respective other transistor 58, 56, so that a cross coupling 63 of collectors and bases of the two transistors 56, 58 of amplifier circuit 22 results.

In the case of control of a transistor with an input signal at its base, the output signal at the collector of the same transistor follows the input signal always with a phase shift of π. The first parallel resonant circuit 18 lies between the collectors of the two transistors 56, 58 and during operation of oscillator circuit 16 generates an additional phase shift of π. Owing to the cross coupling 63, the signal propagated from the collector of transistor 58 to the base of transistor 56 arrives there overall with a phase shift of 2π to the input signal. This also applies conversely, so that the phase requirement for an oscillation is also fulfilled in this respect in the common-emitter circuit of embodiment 22.2.

In each case, FIGS. 3 and 4 show embodiments with a capacitive coupling between an input and an output of differential amplifier circuits. An amplifier circuit with two bipolar transistors in the collector circuit results from the common-emitter circuit in another embodiment by interchanging of the emitter and collector of the two transistors 56, 58 and simultaneous adjustment of the DC potentials VCC, VEE.

Even if the embodiments 22.1, 22.2, described heretofore, of amplifier circuits 22 were explained with use of bipolar NPN transistors 48, 50, 56, 58, it is understood that corresponding embodiments with bipolar PNP transistors or with unipolar transistors of the N-channel type or P-channel type can also be built.

In another preferred embodiment, the values of the first and/or second capacitor 24, 32 in FIG. 2 can be varied continuously and/or stepwise. Examples of known continuously variable capacitive components are varactor, capacitance, Schottky, MOS, and MEM diodes. Examples of capacitive components with a discretely variable capacitance value are so-called CDAC circuits (CDAC=capacitor digital-to-analog converter; compare, for example, U.S. Pat. Appl. No. 2005/0083221), switched MIM capacitors (MIM=metal-insulator-metal), and switched polycaps. It is essential in each case that the capacitors can be integrated into integrated circuits, which applies to the aforementioned embodiments.

The variable capacitors are shown schematically in FIG. 5. FIG. 5a shows an embodiment of first capacitor 24 with a single variable capacitive component. FIG. 5b shows an embodiment of capacitor 32 with two variable capacitive components, between which an AC ground 51 forms. Capacitors 24 and 32 can have similar or different components and have the same or different capacitance values.

With variable capacitors 24, 32, oscillator circuit 16 forms, for example, a voltage controlled oscillator VCO 16. In a VCO 16, for technological reasons, capacitive components are used almost exclusively as actuators for frequency tuning. In this case, the tuning range, therefore the bandwidth of the adjustable resonance frequencies, with increasing frequency is limited by parasitic capacitances of the resonant circuit and/or the amplifier circuit. In the aforementioned embodiment, in which the capacitors of both resonant circuits are tunable, the portion of the overall tunable capacitance of the total capacitance in the arrangement, therefore of the sum of the tunable and parasitic capacitors, is greatly increased in comparison with an arrangement with only one tunable capacitor, because the sum of parasitic capacitors does not change or changes only minimally with the addition of a second tunable capacitor. In this case, it is especially preferred that capacitors 24, 32 are tunable independent of one another to provide additional degrees of freedom during the design and operation of oscillator circuit 16.

As a result, a significant increase in the frequency tuning range of oscillator circuit 16 is thereby achieved. This also applies in comparison with the aforementioned prior art, which does in fact have several resonant circuits but does not have two tunable parallel resonant circuits. With use of the same counting method as in the aforementioned prior art, in the differential embodiment according to FIG. 2 in conjunction with embodiment 5b, four parallel resonant circuits can be identified overall, each of which includes one of the partial inductors 26.1, 26.2, 34.1, 34.2 in conjunction with an assigned portion of first and second capacitors 24, 32.

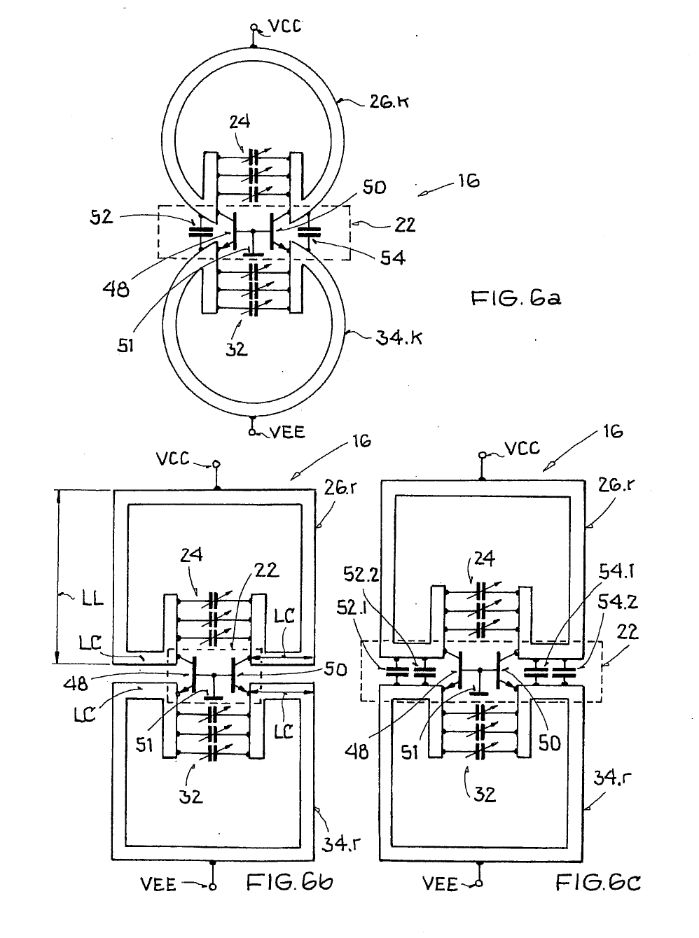

FIG. 6 shows possible geometric embodiments of the resonant circuit inductors and the arrangement of capacitors. FIG. 6a shows an embodiment of an oscillator circuit 16 with a nearly circular first and second inductor 26.k, 34.k. In each case, each resonant circuit inductor 26.k, 34.k includes at least one turn or transmission line. Inductors 28, 26 are divided into left inductors 28.l, 26.l and right inductors 28.r, 26.r by a center tap, to which in each case DC supply 32 is connected. It is understood that other embodiments may also have elliptical conductor loops.

The inductance values of both resonant circuit inductors 26.k, 34.k are preferably the same, but can also assume different values, as a result of which a further degree of freedom is provided in the circuit design. This applies in other respects also to other first and second inductors 26, 34 from the other embodiments, provided that something different is not explicitly described there. Further, FIG. 6a in each case shows first and second capacitors 24, 32 each with three parallel variable capacitive components. It is understood however that this is not associated with a specification of the number three or the type of connection of the capacitive components. This also applies to the design of the amplifier circuit, shown in FIG. 6 without restriction of the stated interchangeability as an embodiment with bipolar NPN transistors 48, 50 in a common-base circuit and coupling capacitors 52, 54.

FIG. 6b shows an embodiment of an oscillator circuit 16 with rectangular conductor loops as inductors 26.r. 34r, in which adjacent and parallel sections LC act as coupling capacitors and together with sections LL, orthogonal thereto, define the length, and/or area of a conductor loop and thereby the inductance. It is possible therefore by changing the lengths LL and LC to vary the value of the inductance, the value of the coupling capacitance, and a portion of a capacitive and transformer coupling of the entire coupling. As a result, additional degrees of freedom in circuit design are provided. Instead of a pure rectangular shape, circular shape, or elliptical shape, other embodiments can also have conductor loops with sections, straight in areas, with a regular or irregular, as well as convex or concave polygon shape and/or conductor loops with concave or convex sections, curved in areas, or hybrid shapes made of curved and straight sections. FIG. 6b therefore shows in particular an embodiment with a combination of transformer and capacitive coupling between an input and an output of the amplifier circuit.

Additional capacitors 52.1, 52.2, 54.1, 54.2, as shown in FIG. 6c, enable optimization of the input and/or output impedance of transistors 48, 50 functioning as amplifiers. In the common-base circuit of transistors 48, 50, as shown here, additional capacitors 52.1, 52.2, 54.1, 54.2 are connected between the collector and emitter, which enables optimized impedance matching. This then results in a maximum power gain and noise matching and therefore also a maximum signal/noise ratio.

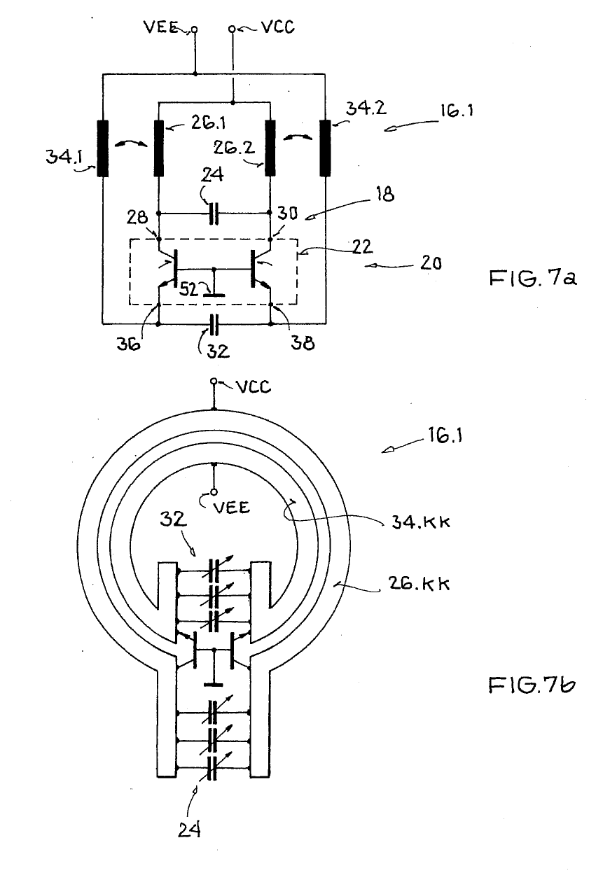

FIG. 7 in part 7a shows a circuit diagram of an embodiment of an oscillator circuit 16.1 with a purely transformer feedback. In this case, resonant circuit inductors 26.1, 34.1 and 26.2, 34.2 of the two parallel resonant circuits 18, 20 are arranged adjacent to one another, to achieve a transformer coupling. The coupling occurs in that the magnetic field of the one resonant circuit inductor 26 penetrates the other resonant circuit inductor 34 and vice versa. The transformer coupling has the advantage of a simplified circuit structure and a reduced space requirement, because no capacitors are needed for a capacitive coupling. In addition, like each inductive or capacitive coupling, it has the advantage of a galvanic separation.

Amplifier circuit 22 in the case of transformer coupling can also have two bipolar NPN transistors 48, 50 in a common-base circuit, as is shown in FIG. 7a. All other embodiments of the aforementioned embodiments of amplifier circuits may also be used, however, therefore two bipolar transistors in a common-emitter circuit or common-collector circuit or realizations with bipolar PNP transistors or with unipolar transistors of the N-channel type or P-channel type.

FIG. 7b shows a possible geometric embodiment of the first and second inductors 26, 34 and the arrangement of capacitors 24, 32 with nearly circular, concentric resonant circuit inductors 26.kk, 34.kk. In each case, each resonant circuit inductor 26.kk, 34.kk includes at least one turn or transmission line. The inductance values of both resonant circuit inductors 26.kk, 34.kk are not identical of necessity in this embodiment. This is not problematic, however, because the resonance frequency of a parallel resonant circuit varies inversely proportional to the root of the product of the resonant circuit inductance and resonant circuit capacitance. In other words: If both resonant circuits are to be tuned to the same resonance frequency, deviations between the inductances can be compensated owing to corresponding deviations between the capacitances of the resonant circuit.

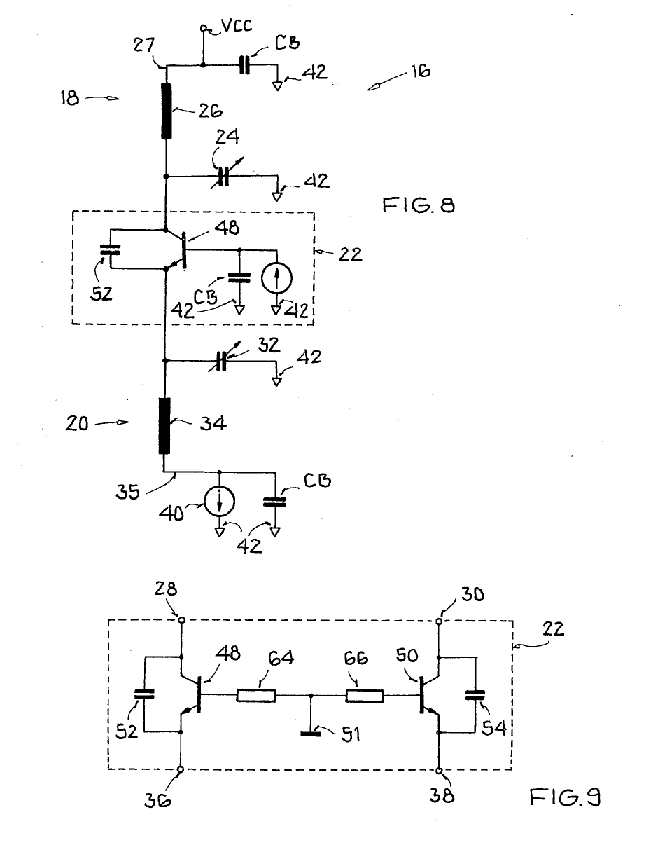

The embodiments presented heretofore related to circuits for differential signals. In general, each of the differential circuits presented above can be divided in the middle. The middle corresponds electrically in each case to an AC ground 51, therefore an AC ground potential, whereby the respective DC potentials can be completely different. In non-differential oscillator circuits, therefore, the nodes of the AC ground can be connected via block capacitors CB to ground 42, whereby parallel current sources are to be provided in addition for setting the operating point. The circuit parts remaining to the right and left of AC ground 51 themselves represent embodiments of the invention. This is explained hereafter with reference to FIG. 8.

FIG. 8 shows an embodiment of an oscillator circuit 16 in a single-ended design. Oscillator circuit 16 has a first resonant circuit 18, a second resonant circuit 20, and an amplifier circuit 22 dedamping both resonant circuits, and a feedback with a coupling capacitor 52. First resonant circuit 18 is a parallel resonant circuit, which has a first capacitor 24 and a first inductor 26 and is connected solely on the output side to amplifier circuit 22. First inductor 26 in addition is connected via a first DC current path 27 to a first DC reference potential VCC. Second resonant circuit 20 is also a parallel resonant circuit and has a second capacitor 32 and a second inductor 34, which is connected via a second DC current path 35 to a second DC reference potential VEE. Second parallel resonant circuit 20 is connected solely on the input side to amplifier circuit 22. The second reference potential VEE in the embodiment of FIG. 8 arises as an output potential of a current source 40, which is referred to a DC ground 42. Amplifier circuit 22 in the embodiment shown in FIG. 8 has a bipolar transistor 48 in a common-base circuit, whose collector is connected to first resonant circuit 18 and whose emitter is connected to second resonant circuit 20. It should be emphasized that the DC connection of the emitter as is necessary for the function of the bipolar transistor within the scope of the invention presented here always occurs via an inductor 34 of second resonant circuit 20.

Apart from the abstracted embodiment of FIG. 1, all oscillator circuits 16 described have a capacitive or transformer feedback. They can therefore be assigned to the type of feedback oscillators. The invention is not limited to use in feedback oscillators, however, but can also be used in reflection oscillators.

FIG. 9 shows an amplifier circuit 22, which in conjunction with the subject matter of FIG. 1 results in a reflection oscillator. Amplifier circuit 22 has two bipolar transistors 48, 50, as are shown in similar form in FIG. 3. In contrast to the subject matter of FIG. 3, the bases of the two transistors 48, 50 are not connected to one another directly, however, but via an impedor 64, 66, for example, another LC network, whereby the connection point forms an AC ground 51. Therefore, the circuit principle of a reflection oscillator is realized in a differential form: Each of the three terminals of the two transistors 48, 50 is connected via an impedor to an AC ground, whereby a negative resistance results in each case at the emitter, over which the resonant circuits involved are dedamped. In this case, the at least one first terminal is connected to an AC ground 51 via the first parallel resonant circuit and the at least one second terminal via the second parallel resonant circuit and the third terminal via an impedor 64, 66 partially or totally reflecting electrical waves. In the case of a completely reflecting impedor 64, 66, coupling capacitors 52, 54, described within the scope of other embodiments, can be dispensed with. In a partially reflecting impedor 64, 66, it is advantageous to provide in addition separate couplings by capacitors 52, 54 or a corresponding arrangement of the inductors.

1-20. (canceled)

21. An integrated oscillator circuit comprising:
an amplifier circuit; and
a frequency-selective feedback network comprising a first resonant circuit and a second resonant circuit,
wherein the first resonant circuit is connected to the amplifier circuit solely on an output side and is formed as a parallel resonant circuit comprising a first capacitor and a first inductor,
wherein the second resonant circuit is connected to the amplifier circuit solely on an input side and is formed as a parallel resonant circuit comprising a second capacitor and a second inductor, and
wherein a transformer coupling is provided between an output and an input of the amplifier circuit.

22. The oscillator circuit according to claim 21, wherein the second inductor and the second capacitor have fixed values.

23. The oscillator circuit according to claim 22, wherein the fixed values of the second inductor and the second capacitor together with values for parasitic capacitors of the amplifier circuit together fulfill a resonance condition.

24. The oscillator circuit according to claim 21, wherein the capacitor of the second resonant circuit has a variable capacitance value.

25. The oscillator circuit according to claim 21, wherein the first inductor is connected via a first DC current path to a first DC reference potential, and the second inductor is connected via a second DC current path to a second DC reference potential.

26. The oscillator circuit according to claim 21, comprising a capacitive coupling between an output and an input of the amplifier circuit.

27. The oscillator circuit according to claim 21, comprising a transformer coupling between circular, concentric first inductors and second inductors.

28. The oscillator circuit according to one claim 21, comprising an amplifier circuit, which has at least one bipolar transistor in a common-base circuit, common-emitter circuit, or common-collector circuit.

29. The oscillator circuit according to claim 21, comprising an amplifier circuit, which has at least one unipolar transistor in a gate circuit, source circuit, or drain circuit.

30. The oscillator circuit according to claim 21, wherein the first capacitor has a variable capacitance value.

31. The oscillator circuit according to claim 24, wherein values of the first capacitor and the second capacitor are variable independently of one another.

32. The oscillator circuit according to claim 21, wherein the inductance values of the first inductor and the second inductor are the same.

33. The oscillator circuit according to claim 21, wherein the inductance values of the first inductor and the second inductor are different.

34. The oscillator circuit according to claim 21, wherein the first inductor and the second inductor each have at least one rectangular conductor loop.

35. The oscillator circuit according to claim 21, wherein the first inductor and the second inductor each have at least one conductor loop with sections, straight in areas, with a regular or irregular, as well as convex or concave polygon shape or at least one conductor loop with concave or convex sections, curved in areas, or at least one conductor loop made of curved and straight sections.

36. The oscillator circuit according to claim 21, further comprising a differential amplifier circuit.

37. The oscillator circuit according to claim 21, further comprising a single-ended amplifier circuit.

38. The oscillator circuit according to claim 21, wherein the first resonant circuit is connected to at least one output of the amplifier circuit and the second resonant circuit is connected to at least one input of the amplifier circuit.

39. The oscillator circuit according to claim 21, further comprising: an amplifier circuit with at least one first terminal, at least one second terminal, and at least one third terminal, each of which is connected to an AC ground over a respective impedance, wherein the at least one first terminal is connected to an AC ground via the first parallel resonant circuit and the at least one second terminal via the second parallel resonant circuit and the third terminal via an impedor partially or totally reflecting electrical waves.
